(19) United States
(12) Patent Application Publication
(10) Pub. No.: US 2022/0003866 A1
(43) Pub. Date: Jan. 6, 2022

(54) OPTICAL MODULE AND DISTANCE-MEASURING DEVICE

(71) Applicant: SONY SEMICONDUCTOR SOLUTIONS CORPORATION, KANAGAWA (JP)

(72) Inventor: SHUNJI MAEDA, KANAGAWA (JP)

(21) Appl. No.: 17/290,837

(22) PCT Filed: Oct. 17, 2019
(86) PCT No.: PCT/JP2019/040888

§ 371 Date: May 3, 2021

(30) Foreign Application Priority Data
Nov. 12, 2018 (JP) 2018-212133

(51) Int. Cl. G01S 17/10; G01S 7/4863; G01S 7/481

(52) U.S. Cl. CPC G01S 17/10; G01S 7/4812; G01S 7/4813; G01S 7/4863

(57) ABSTRACT

An optical module according to the present disclosure includes: a light-emitting section (10) configured to emit light; a light-receiving section (20) including a first light-receiving section and a second light-receiving section; a first cover part (30) provided on a light emission side of the light-emitting section (10), and configured to guide first light (L1) that is a portion of the light emitted from the light-emitting section (10) in a direction of a target (2) and guide second light (L2) that is another portion of the light emitted from the light-emitting section (10) in a direction different from the direction of the target (2); and a second cover part (40) provided on a light incidence side of the light-receiving section (20), and configured to guide reflected light (L1R) that is the first light (L1) reflected by the target (2) in a direction of the first light-receiving section and guide the second light (L2) guided from the first cover part (30) in a direction of the second light-receiving section.

### TECHNICAL FIELD

The present disclosure relates to a distance-measuring device that measures a distance to a target, and an optical module to be used in such a distance-measuring device.

### BACKGROUND ART

Distance-measuring devices use, for example, a passive method of not applying light and an active method of applying light. Passive methods include a multi-eye method, etc., and active methods include a TOF (time of flight) method, etc.

The TOF method is a method of measuring delay time of light reflected back by a measurement target, and measuring a distance to the target on the basis of the delay time (e.g., see PTL 1).

### CITATION LIST

### Patent Literature

PTL 1: U.S. Unexamined Patent Application Publication No. 2018/0026058

### SUMMARY OF THE INVENTION

Incidentally, in a distance-measuring device, it is desirable to more easily provide an optical path for calibration of a distance to a distance-measuring target obtained from the distance-measuring device.

It is desirable to provide a distance-measuring device that makes it possible to more easily provide an optical path for calibration of a distance to a distance-measuring target, and an optical module to be used in the distance-measuring device.

An optical module according to one embodiment of the present disclosure includes a light-emitting section, a light-receiving section, a first cover part, and a second cover part. The light-emitting section is configured to emit light. The light-receiving section includes a first light-receiving section and a second light-receiving section. The first cover part is provided on a light emission side of the light-emitting section. The first cover part is configured to guide first light that is a portion of the light emitted from the light-emitting section in a direction of a target and guide second light that is another portion of the light emitted from the light-emitting section in a direction different from the direction of the target. The second cover part is provided on a light incidence side of the light-receiving section. The second cover part is configured to guide reflected light that is the first light reflected by the target in a direction of the first light-receiving section and guide the second light guided from the first cover part in a direction of the second light-receiving section.

A distance-measuring device according to one embodiment of the present disclosure includes a light-emitting section, a light-receiving section, a first cover part, a second cover part, and a processor. The light-emitting section is configured to emit light. The light-receiving section includes a first light-receiving section and a second light-receiving section. The first cover part is provided on a light emission side of the light-emitting section. The first cover part is configured to guide first light that is a portion of the light emitted from the light-emitting section in a direction of a target and guide second light that is another portion of the light emitted from the light-emitting section in a direction different from the direction of the target. The second cover part is provided on a light incidence side of the light-receiving section. The second cover part is configured to guide reflected light that is the first light reflected by the target in a direction of the first light-receiving section and guide the second light guided from the first cover part in a direction of the second light-receiving section. The processor is configured to calculate a distance to the target on the basis of a first pixel signal outputted from the first light-receiving section in response to the reflected light incident on the first light-receiving section. The processor is also configured to calibrate the distance on the basis of a second pixel signal outputted from the second light-receiving section in response to the second light incident on the second light-receiving section.

In the optical module according to one embodiment of the present disclosure, the first light that is a portion of the light emitted from the light-emitting section is transmitted through the first cover part to enter the target, and the reflected light from the target is transmitted through the second cover part to enter the first light-receiving section. On the other hand, the second light that is another portion of the light emitted from the light-emitting section is guided in the direction different from the target by the first cover part and is guided to the second light-receiving section by the second cover part to enter the second light-receiving section.

In the distance-measuring device according to one embodiment of the present disclosure, the first light that is a portion of the light emitted from the light-emitting section is transmitted through the first cover part to enter the target, and the reflected light from the target is transmitted through the second cover part to enter the first light-receiving section. Then, on the basis of the first pixel signal from the first light-receiving section, the distance to the target is calculated. On the other hand, the second light that is another portion of the light emitted from the light-emitting section is guided in the direction different from the target by the first cover part and is guided to the second light-receiving section by the second cover part to enter the second light-receiving section. Then, on the basis of the second pixel signal from the second light-receiving section, the distance to the target is calibrated.

### BRIEF DESCRIPTION OF DRAWINGS

FIG. 1 is a schematic diagram illustrating an example configuration of a distance-measuring device according to one embodiment of the present disclosure.

FIG. 2 is a perspective view of an example configuration of a main part of the distance-measuring device illustrated in FIG. 1.

FIG. 3 is a perspective view of an example configuration of a light-emitting section and a light-receiving section of the distance-measuring device illustrated in FIG. 1.

FIG. 4 is a plan view of an example configuration of the light-emitting section and the light-receiving section of the distance-measuring device illustrated in FIG. 1.

FIG. 5 is a perspective view of an example configuration of a first cover part and a second cover part of the distance-measuring device illustrated in FIG. 1.

FIG. 6 is a cross-sectional perspective view of an example configuration of the distance-measuring device illustrated in FIG. 1.

FIG. 7 is an explanatory diagram illustrating an example operation of the distance-measuring device illustrated in FIG. 1.

FIG. 8 is a timing diagram illustrating an optical output waveform of the light-emitting section and an optical input waveform of the light-receiving section in a case of performing distance measuring by a direct method by the distance-measuring device illustrated in FIG. 1.

FIG. 9 is an explanatory diagram illustrating deviation between an actual distance and a distance measured by the distance-measuring device using the direct method.

FIG. 10 is a perspective view of an example configuration of a main part of a distance-measuring device according to Modification Example 1.

FIG. 11 is a perspective view of an example configuration of a recess of a first cover part of the distance-measuring device illustrated in FIG. 10.

FIG. 12 is a plan view of an example configuration of first light-receiving pixels and a second light-receiving pixel of the distance-measuring device illustrated in FIG. 10.

FIG. 13 is a plan view of an example configuration of first light-receiving pixels and second light-receiving pixels of a distance-measuring device according to Modification Example 2.

FIG. 14 is a perspective view of an example configuration of a main part of a distance-measuring device according to Modification Example 3.

FIG. 15 is a perspective view of an example configuration of a main part of a distance-measuring device according to Modification Example 4.

FIG. 16 is a perspective view of an example configuration of a main part of a distance-measuring device according to Modification Example 5.

FIG. 17 is a cross-sectional perspective view of a configuration of the distance-measuring device illustrated in FIG. 16.

FIG. 18 is a perspective view of an example configuration of a main part of a distance-measuring device according to Modification Example 6.

FIG. 19 is a plan view of an example configuration of a light-emitting section and a light-receiving section of a distance-measuring device according to Modification Example 7.

FIG. 20 is a timing diagram illustrating an optical output waveform of the light-emitting section and an optical input waveform of the light-receiving section in a case of performing distance measuring by an indirect method.

FIG. 21 is an explanatory diagram explaining deviation between an actual distance and a distance measured by the distance-measuring device using the indirect method.

FIG. 22 is a block diagram depicting an example of schematic configuration of a vehicle control system.

FIG. 23 is a diagram of assistance in explaining an example of installation positions of an outside-vehicle information detecting section and an imaging section.

FIG. 24 is a plan view of an example configuration of a light-receiving section of a distance-measuring device according to a modification example.

### MODES FOR CARRYING OUT THE INVENTION

In the following, description is given of embodiments of the present disclosure in detail with reference to the drawings. It is to be noted that the description is given in the following order.
1. Embodiment (an example in which first and second cover parts are provided with recesses having reflecting surfaces)
2. Modification Example 1 (an example in which the reflecting surface of the second cover part and a second light-receiving section are provided to extend in one direction)
3. Modification Example 2 (an example in which the second light-receiving section is provided to include a plurality of pixels)
4. Modification Example 3 (an example in which the reflecting surface of the second cover part and the second light-receiving section are provided to extend in one direction)
5. Modification Example 4 (an example in which the reflecting surface of the second cover part is provided to extend in one direction)
6. Modification Example 5 (an example in which the first and second cover parts are integrally configured)
7. Modification Example 6 (an example in which the first and second cover parts are provided with protrusions having reflecting surfaces)
8. Modification Example 7 (an example in which a position of the second light-receiving section is shifted from on the shortest line coupling a pixel included in a first light-receiving section and a monitoring light-emitting body)
9. Modification Example 8 (an example of performing distance measuring by an indirect method)
10. Example of Application to Mobile Body

### 1. EMBODIMENT

### CONFIGURATION EXAMPLE

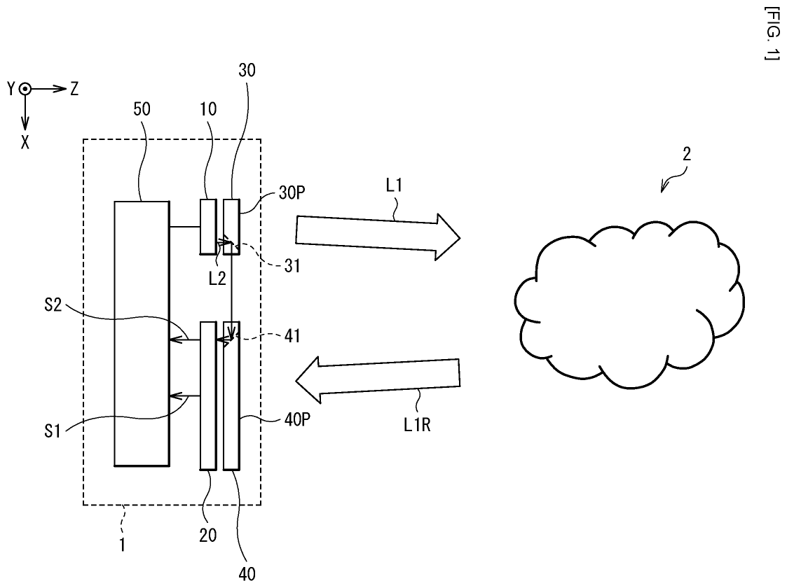

FIG. 1 illustrates an example configuration of a distance-measuring device (a distance-measuring device 1) according to one embodiment. The distance-measuring device 1 is a device that irradiates a distance-measuring target 2 with light L1, detects reflected light L1R reflected by the distance-measuring target 2, and measures a distance to the distance-measuring target 2 on the basis of a result of the detection. The distance-measuring device 1 includes a light-emitting section 10, a light-receiving section 20, a first cover part 30, a second cover part 40, and a processor 50. Of the distance-measuring device 1, the light-emitting section 10, the light-receiving section 20, the first cover part 30, and the second cover part 40 may be configured as an optical module.

The light-emitting section 10 includes, for example, any light-emitting body serving as a light source, such as a laser (LASER (Light Amplification by Stimulated Emission)) or an LED (Light Emitting Diode), and is configured to emit light. The laser may include, for example, a VCSEL (Vertical Cavity Surface Emitting LASER). The light emitted from the light-emitting section 10 is, for example, infrared light. Further, the light emitted from the light-emitting section 10 is, for example, pulsed light. Partial light (light L1) of the light emitted from the light-emitting section 10 is emitted to the outside through the first cover part 30 to irradiate the distance-measuring target 2.

The light-receiving section 20 is configured to receive incident light and convert it into an electric signal. The light-receiving section 20 has sensitivity to at least the light emitted from the light-emitting section 10. The light-receiving section 20 includes a first light-receiving section 21A and a second light-receiving section 21B. The first light-receiving section 21A includes one or more pixels. The first light-receiving section 21A is configured such that the reflected light L1R emitted from the light-emitting section 10 and reflected by the distance-measuring target 2 enters through the second cover part 40. The first light-receiving section 21A converts the reflected light L1R reflected by the distance-measuring target 2 into a first pixel signal S1, and outputs the first pixel signal S1 to the processor 50. Further, the second light-receiving section 21B of the light-receiving section 20 includes one or more pixels. Light received by the second light-receiving section 21B and a pixel signal generated by the second light-receiving section 21B will be described later.

The first cover part 30 is provided on a light emission side of the light-emitting section 10. For example, the first cover part 30 is held by a holder or the like so as to be spaced apart from the light-emitting section 10. Alternatively, in a case where the light-emitting section 10 is a packaged light-emitting section, a cap of the package may be configured to be the first cover part 30. The first cover part 30 includes a material that is transparent to the light emitted from the light-emitting section 10, and includes, for example, glass or plastic. The first cover part 30 has a plate-like shape as a whole. The first cover part 30 prevents dust or the like from adhering to the light-emitting section 10, protecting the light-emitting section 10 from the outside atmosphere.

In the present embodiment, the first cover part 30 is partly provided with a first reflecting surface 31. In a portion of the first cover part 30 where the first reflecting surface 31 is not provided, partial light of the light emitted from the light-emitting section 10 is transmitted through the first cover part 30 to be guided in a direction of the distance-measuring target 2. The light transmitted through the first cover part 30 to be guided in the direction of the distance-measuring target 2 corresponds to the light L1 applied to the distance-measuring target 2. Further, in a portion of the first cover part 30 where the first reflecting surface 31 is provided, other partial light of the light emitted from the light-emitting section 10 is reflected by the first reflecting surface 31 to be guided in a direction different from the direction of the distance-measuring target 2. The light reflected by the first reflecting surface 31 to be guided in the direction different from the direction of the distance-measuring target 2 is illustrated as light L2 in FIG. 1. In the present embodiment, the first reflecting surface 31 is an oblique surface having an angle of 45° with respect to a principal surface 30P of the first cover part 30. Here, the principal surface 30P of the first cover part 30 refers to a surface of the first cover part 30 that is substantially parallel to an XY plane and located on the far side in a Z-axis direction as viewed from the light-emitting section 10. The light L2 reflected by the first reflecting surface 31 is guided in a direction of the second cover part 40. As described above, the first cover part 30 guides partial light (light L1) of the light emitted from the light-emitting section 10 in the direction of the distance-measuring target 2 and guides other partial light (light L2) of the light emitted from the light-emitting section 10 in the direction different from the direction of the distance-measuring target 2.

The second cover part 40 is provided on a light incidence side of the light-receiving section 20. For example, the second cover part 40 is held by a holder or the like so as to be spaced apart from the light-receiving section 20. Like the first cover part 30, the second cover part 40 includes a material that is transparent to the light emitted from the light-emitting section 10, and includes, for example, glass or plastic. The second cover part 40 has a plate-like shape as a whole. The second cover part 40 prevents dust or the like from adhering to the light-receiving section 20, protecting the light-receiving section 20 from the outside atmosphere.

In the present embodiment, the second cover part 40 is partly provided with a second reflecting surface 41. In a portion of the second cover part 40 where the second reflecting surface 41 is not provided, the reflected light L1R reflected by the distance-measuring target 2 is transmitted through the second cover part 40 to be guided in a direction of the first light-receiving section 21A of the light-receiving section 20. The second reflecting surface 41 is an oblique surface having an angle of 45° with respect to a principal surface 40P of the second cover part 40. Here, the principal surface 40P of the second cover part 40 refers to a surface of the second cover part 40 that is substantially parallel to the XY plane and located on the far side in the Z-axis direction as viewed from the light-receiving section 20. The light L2 reflected by the first reflecting surface 31 to be guided to the second cover part 40 is reflected by the second reflecting surface 41 to be guided in a direction of the second light-receiving section 21B of the light-receiving section 20. As described above, the second cover part 40 guides the light (reflected light L1R) reflected by the distance-measuring target 2 in the direction of the first light-receiving section 21A and guides the light (light L2) guided from the first cover part 30 in the direction of the second light-receiving section 21B.

The reflected light L1R reflected by the distance-measuring target 2 enters the first light-receiving section 21A of the light-receiving section 20 to be converted into the first pixel signal S1. The first pixel signal S1 is outputted to the processor 50. Further, other partial light (light L2) emitted from the light-emitting section 10 and reflected by the first reflecting surface 31 of the first cover part 30 and the second reflecting surface 41 of the second cover part enters the second light-receiving section 21B of the light-receiving section 20 to be converted into a second pixel signal S2. The second pixel signal S2 is outputted to the processor 50.

The processor 50 is configured to drive the light-emitting section 10 to cause each light-emitting body 11 of the light-emitting section 10 to emit light. Further, the processor 50 is configured to calculate the distance between the distance-measuring device 1 and the distance-measuring target 2 on the basis of the first pixel signal S1 outputted from the first light-receiving section 21A in response to the reflected light L1R incident on the first light-receiving section 21A of the light-receiving section 20. The processor 50 is also configured to calibrate the distance between the distance-measuring device 1 and the distance-measuring target 2 on the basis of the second pixel signal S2 outputted from the second light-receiving section 21B in response to the light L2 incident on the second light-receiving section 21B of the light-receiving section 20 through the first cover part 30 and the second cover part 40.

In the distance-measuring device 1, a light diffuser, an optical filter such as a band-pass filter, a lens, or another optical member may be appropriately provided, as necessary, on an optical path taken until partial light of the light emitted from the light-emitting section 10 is reflected by the distance-measuring target 2 to enter the first light-receiving section 21A of the light-receiving section 20. Similarly, a light diffuser, an optical filter such as a band-pass filter, a lens, or another optical member may be appropriately provided, as necessary, on an optical path taken until other partial light of the light emitted from the light-emitting section 10 enters the second light-receiving section 21B of the light-receiving section 20 through the first cover part 30 and the second cover part 40.

### DETAILED CONFIGURATION EXAMPLE

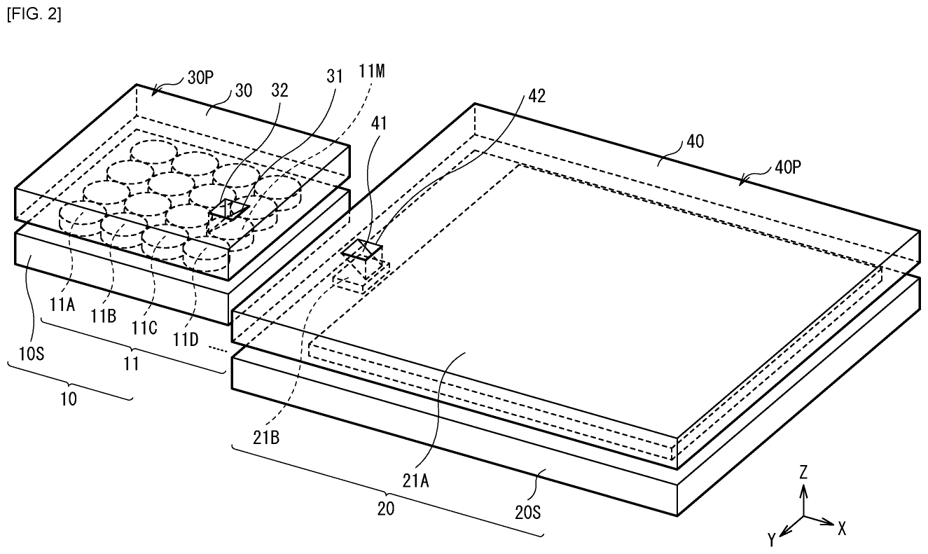

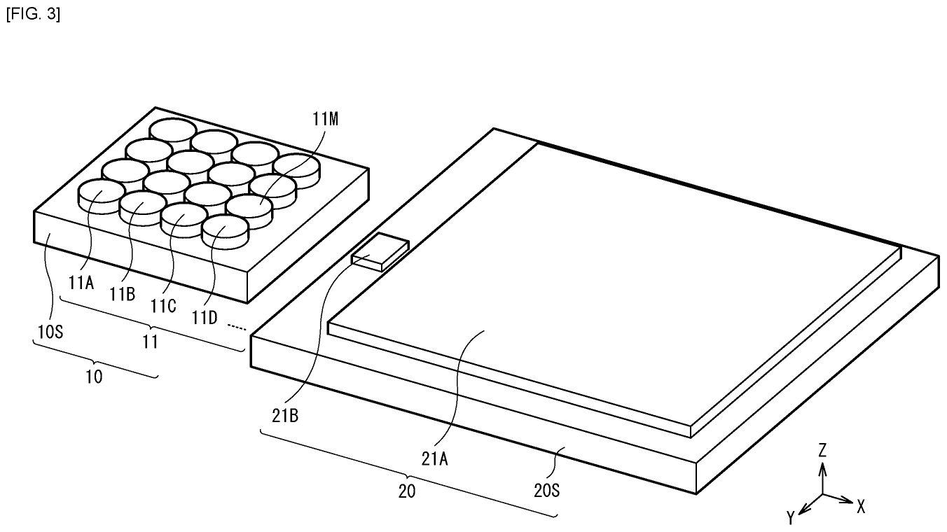

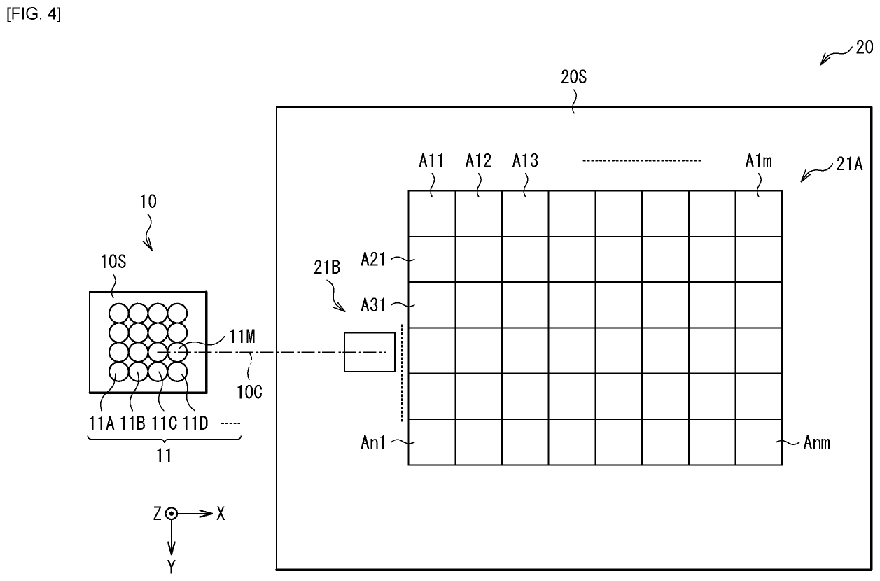

FIG. 2 illustrates an example configuration of a main part of the distance-measuring device 1. FIG. 2 illustrates the light-emitting section 10, the light-receiving section 20, the first cover part 30, and the second cover part 40 of the distance-measuring device 1. FIGS. 3 and 4 illustrate an example configuration of the light-emitting section 10 and the light-receiving section 20 of the distance-measuring device 1.

The light-emitting section 10 includes a light-emitting section substrate 10S, and a plurality of light-emitting bodies 11 (light-emitting bodies 11A, 11B, 11C, 11D . . . ) arranged in a matrix on the light-emitting section substrate 10S. Although four by four (four in an X-axis direction and four in a Y-axis direction), i.e., sixteen, light-emitting bodies 11 are arranged in the drawing, this number is non-limiting, and it is sufficient that one or more light-emitting bodies are provided. The light-emitting body 11 includes, for example, a laser such as a VCSEL, an LED, or the like. Partial light of the light emitted from the light-emitting section 10 is light (light L1) guided in the direction of the distance-measuring target 2 described above to irradiate the distance-measuring target 2. Other partial light of the light emitted from the light-emitting section 10 is light (light L2) that enters the second light-receiving section 21B of the light-receiving section 20 through the first cover part 30 and the second cover part 40. The light L2 is also referred to as monitoring light, and a light-emitting body that emits the light L2 is also referred to as a monitoring light-emitting body 11M. One light-emitting body 11 is illustrated as the monitoring light-emitting body 11M in FIGS. 2 and 3; without being limited thereto, two or more light-emitting bodies 11 may be the monitoring light-emitting body 11M. In addition, light emitted by one or two or more light-emitting bodies 11 may partly be used as monitoring light.

The light-receiving section 20 is provided on the X-axis direction side of the light-emitting section 10. The light-receiving section 20 includes a light-receiving section substrate 20S, and the first light-receiving section 21A and the second light-receiving section 21B provided on the light-receiving section substrate 20S. The first light-receiving section 21A is provided on the far side in the X-axis direction as viewed from the light-emitting section 10, and the second light-receiving section 21B is provided on the near side. Pixels of the first light-receiving section 21A and the second light-receiving section 21B each receive incident light, and output an electric signal corresponding to an amount of the received light. The first light-receiving section 21A is a pixel array and includes, for example, n×m (m in the X-axis direction and n in the Y-axis direction) pixels arranged in a matrix (pixels A11 to Anm). Each pixel includes a light-receiving element such as a PD (photodiode, photodiode). In addition, the second light-receiving section 21B includes one pixel. Although illustrated to include one pixel in the drawing, it may include two or more pixels. The second light-receiving section 21B includes a light-receiving element such as a PD. In this example, the first light-receiving section 21A and the second light-receiving section 21B are configured as separate bodies. In the configuration of the light-emitting section 10 and the light-receiving section 20 illustrated in FIG. 4, in the present embodiment, the second light-receiving section 21B is formed smaller than the first light-receiving section 21A in both the X-axis direction and the Y-axis direction. The second light-receiving section 21B is provided so as to be localized at a position corresponding to the vicinity of the middle of the first light-receiving section 21 in the Y-axis direction. The second light-receiving section 21B is located on the shortest line (dash-dot line 10C) coupling a pixel included in the first light-receiving section 21A and the monitoring light-emitting body 11M.

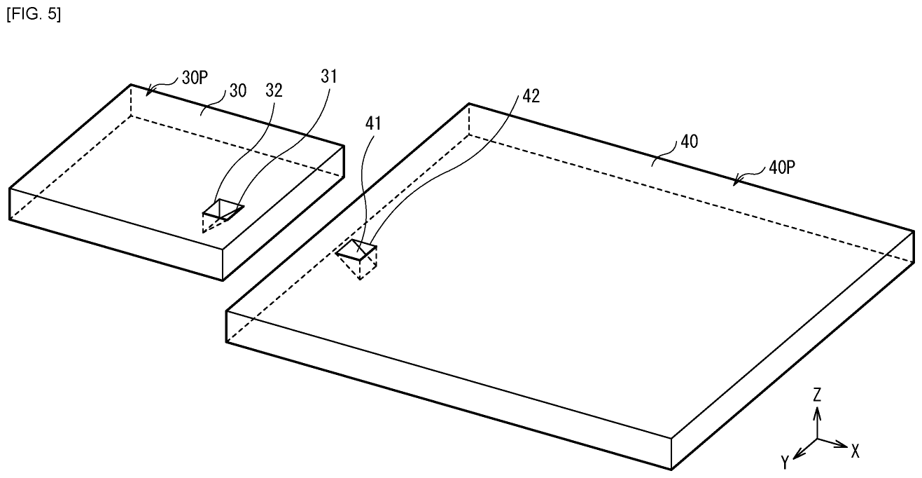

FIG. 5 illustrates an example configuration of the first cover part 30 and the second cover part 40 of the distance-measuring device 1. The first cover part 30 has a plate-like shape, and is partly provided with a first recess 32. A portion of an inner wall of the first recess 32 is the first reflecting surface 31 that is an oblique surface having an angle of 45° with respect to the principal surface 30P of the first cover part 30. The inner wall of the first recess 32 is in contact with the air. In a case where the first cover part 30 includes glass, it is possible to form the first recess 32 by counterboring, blasting, or the like. Further, in a case where the first cover part 30 includes plastic, it is possible to form the first recess 32 by molding. The first reflecting surface 31 reflects monitoring light emitted from the monitoring light-emitting body 11M in accordance with a difference between a refractive index of the material constituting the first cover part 30 and a refractive index of the air, and guides the monitoring light in the direction different from the direction of the distance-measuring target 2. To increase reflectance of light on the first reflecting surface 31, a reflective film including silver or another metallic film or the like may be provided on the first reflecting surface 31. Alternatively, a light-shielding material film may be provided on the first reflecting surface 31. Alternatively, the first recess 32 may be filled with a material having a refractive index different from that of the material constituting the first cover part 30. Alternatively, the first recess 32 may be filled with a light-shielding material. Further, the first reflecting surface 31 may not necessarily be totally reflective or highly reflective. For example, the light emitted from the monitoring light-emitting body 11M and incident on the portion of the first recess 32 may partly be reflected to be used as monitoring light, and the remainder may be transmitted and guided in the direction of the distance-measuring target 2 to be used as light (light L1) applied to the distance-measuring target 2.

The second cover part 40 has a plate-like shape, and is partly provided with a second recess 42. A portion of an inner wall of the second recess 42 is the second reflecting surface 41 that is an oblique surface having an angle of 45° with respect to the principal surface 40P of the second cover part 40. The inner wall of the second recess 42 is in contact with the air. The second recess 42 may be formed in a manner similar to that of the first recess 32. The second reflecting surface 41 reflects monitoring light emitted from the monitoring light-emitting body 11M and reflected by the first reflecting surface 31 in accordance with a difference between a refractive index of the material constituting the second cover part 40 and the refractive index of the air, and guides the monitoring light in the direction of the second light-receiving section 21B. To increase reflectance of light on the second reflecting surface 41, for example, a reflective film including silver or another metallic film or the like may be provided on the second reflecting surface 41, a light-shielding material film may be provided on the second reflecting surface 41, the second recess 42 may be filled with a material having a refractive index different from that of the material constituting the second cover part 40, or the second recess 42 may be filled with a light-shielding material. Further, the second reflecting surface 41 may not necessarily be totally reflective or highly reflective.

The first cover part 30 and the second cover part 40 are aligned such that an optical path of the monitoring light L2 is provided. The first cover part 30 and the second cover part 40 are large enough to make it possible to easily adjust the optical path of the monitoring light L2.

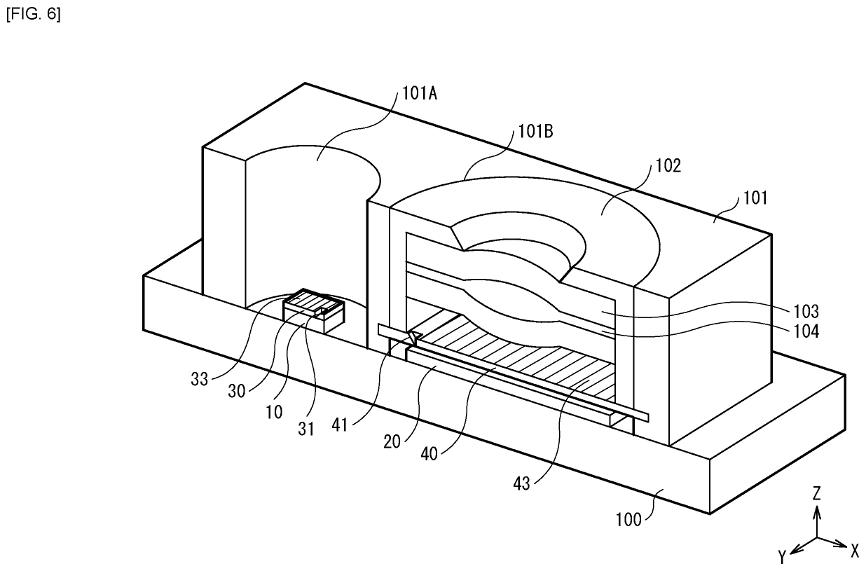

FIG. 6 illustrates an example cross-sectional structure of the distance-measuring device 1. A holder 101 is disposed on a substrate 100. The holder 101 is provided with a light-emitting section opening 101A and a light-receiving section opening 101B. Inside the light-emitting section opening 101A, the light-emitting section 10 that is packaged is disposed on the substrate 100. The packaged light-emitting section 10 is provided with the first cover part 30 as a cap of the package. The first cover part 30 is provided with the first reflecting surface 31. Further, on the first cover part 30 is formed a light diffusing film 33 for diffusion of the light emitted from the light-emitting section 10 in the direction of the distance-measuring target 2.

Further, the light-receiving section 20 is disposed on the substrate 100 inside the light-receiving section opening 101B. The second cover part 40 is provided on the light incidence side of the light-receiving section 20. The second cover part 40 is provided with the second reflecting surface 41. Further, the second cover part 40 is provided with an infrared filter 43 for transmission of infrared light that is light from the light-emitting section 10. Further, a lens holder 102 is provided inside the light-receiving section opening 101B. The lens holder 102 holds lenses 103 and 104. Further, the substrate 100 may be provided with the processor 50 coupled to the light-emitting section 10 and the light-receiving section 20. Alternatively, the light-emitting section 10 and the light-receiving section 20 may be coupled to the processor 50 provided separately via the substrate 100. In addition to the above, further optical members may be appropriately provided in the light-emitting section opening 101A and the light-receiving section opening 101B.

Here, the light-emitting section 10 corresponds to one specific example of a “light-emitting section” in the present disclosure. The light-receiving section 20 corresponds to one specific example of a “light-receiving section” in the present disclosure. The first cover part 30 corresponds to one specific example of a “first cover part” in the present disclosure. The second cover part 40 corresponds to one specific example of a “second cover part” in the present disclosure. The processor 50 corresponds to one specific example of a “processor” in the present disclosure.

### [Operation and Workings]

Next, the operation and workings of the distance-measuring device of the present embodiment will be described.

### (Overview of Overall Operation)

First, an overview of the overall operation of the distance-measuring device will be described with reference to FIG. 1. By being driven by the processor 50, the light-emitting section 10 emits light. Partial light (light L1) of the light emitted from the light-emitting section 10 is transmitted through the first cover part 30 and guided in the direction of the distance-measuring target 2 to irradiate the distance-measuring target 2. The light L1 is reflected by the distance-measuring target 2 to become the reflected light L1R, and enters the first light-receiving section 21A of the light-receiving section 20. The first light-receiving section 21A receives the reflected light L1R and outputs the first pixel signal S1 to the processor 50. On the basis of the first pixel signal S1, the processor 50 calculates the distance to the distance-measuring target 2, on the basis of time taken until the light emitted from the light-emitting section 10 is reflected by the distance-measuring target 2 to enter the light-receiving section 20. On the other hand, other partial light (monitoring light L2) of the light emitted from the light-emitting section 10 is reflected by the first reflecting surface 31 of the first cover part 30 to be guided in the direction of the second cover part 40, and is reflected by the second reflecting surface 41 of the second cover part 40 to enter the second light-receiving section 21B of the light-receiving section 20. The second light-receiving section 21B receives the monitoring light L2 and outputs the second pixel signal S2 to the processor 50. The processor 50 creates a measured distance correction value table in advance on the basis of the second pixel signal S2. The processor 50 calculates the distance to the distance-measuring target 2 on the basis of the first pixel signal S1, refers to the correction value table to obtain a correction value corresponding to the distance obtained from the first pixel signal S1, and calibrates the distance to the distance-measuring target 2 with the obtained correction value.

### (Detailed Operation)

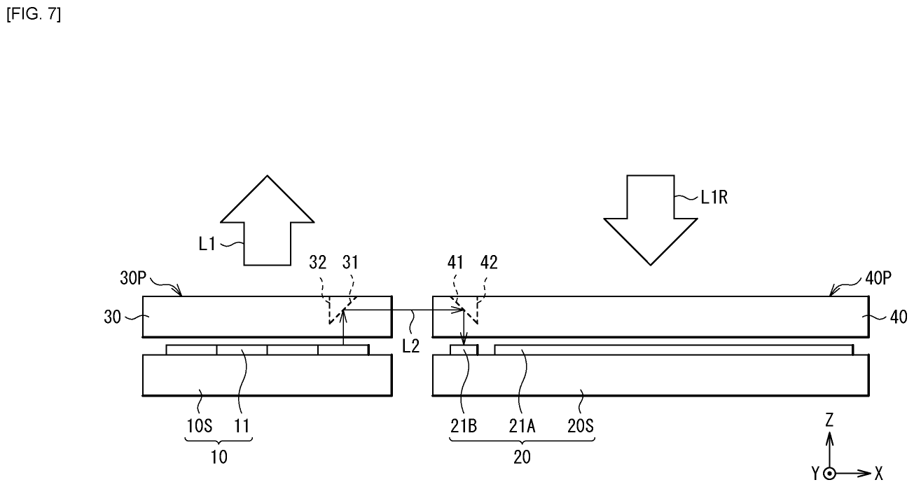

FIG. 7 illustrates an example operation of the distance-measuring device 1. By being driven by the processor 50, each light-emitting body 11 of the light-emitting section 10 emits light in a direction of the first cover part 30.

Partial light (light L1) of the light incident on a portion of the first cover part 30 where the first recess 32 is not provided is transmitted through the first cover part 30 and guided in the direction of the distance-measuring target 2 to irradiate the distance-measuring target 2. The light L1 is reflected by the distance-measuring target 2 to become the reflected light L1R, and enters the first light-receiving section 21A of the light-receiving section 20.

On the other hand, other partial light (monitoring light L2) of the light incident on a portion of the first cover part 30 where the first recess 32 is provided is reflected by the first reflecting surface 31 provided in the first recess 32 to be guided in the direction of the second cover part 40. The monitoring light L2 guided to the second cover part 40 is reflected by the second reflecting surface 41 provided in the second recess 42 to enter the second light-receiving section 21B of the light-receiving section 20.

The first light-receiving section 21A receives the reflected light L1R and outputs the first pixel signal S1 to the processor 50. Each of the n×m pixels arranged in a matrix in the first light-receiving section 21A outputs the first pixel signal S1. Further, the second light-receiving section 21B receives the monitoring light L2 and outputs the second pixel signal S2 to the processor 50.

For the measurement of the distance to the distance-measuring target 2 by the distance-measuring device 1 illustrated in FIG. 1, for example, a direct method and an indirect method are applicable; the present embodiment will be described taking the direct method. On the basis of the first pixel signal S1, the processor 50 measures the time taken until the light emitted from the light-emitting section 10 is reflected by the distance-measuring target 2 to enter the light-receiving section 20, and calculates the distance to the distance-measuring target 2 from the obtained time. For each of the n×m pixels of the first light-receiving section 21A, the measurement of the time taken until the light emitted from the light-emitting section 10 is reflected by the distance-measuring target 2 to enter the light-receiving section 20, and the calculation of the distance to the distance-measuring target 2 based on the obtained time are performed. In addition, the processor 50 calibrates the distance to the distance-measuring target 2 on the basis of the second pixel signal S2. Details of the calibration will be described later. The calibration of the distance to the distance-measuring target 2 based on the second pixel signal S2 is performed for each of the n×m pixels of the first light-receiving section 21A.

The processor 50 measures the time taken until the light emitted from the light-emitting section 10 is reflected by the distance-measuring target 2 to enter the light-receiving section 20 on the basis of the first pixel signal S1 outputted from the first light-receiving section 21A of the light-receiving section 20 by the direct method, and calculates the distance between the distance-measuring device 1 and the distance-measuring target 2 on the basis of the obtained time, in the following manner.

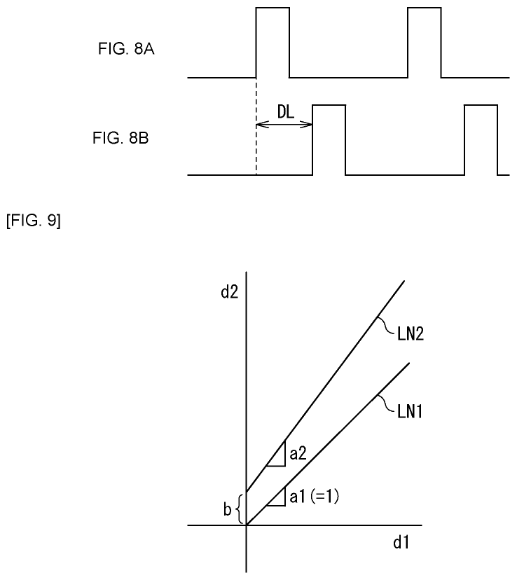

FIG. 8 illustrates an example operation in a case of performing distance measuring by the direct method by the distance-measuring device 1; (A) illustrates an optical output waveform (emitted pulse) of the light-emitting section 10, and (B) illustrates an optical input waveform (incident pulse) of the light-receiving section. The optical output waveform of the light-emitting section 10 ((A) of FIG. 8) is an output waveform of light immediately after being emitted from the light-emitting section 10 and has, for example, a pulse shape.

The optical input waveform of the light-receiving section 20 ((B) of FIG. 8) is a waveform of light when the light (reflected light L1R) emitted from the light-emitting section 10 and reflected by the distance-measuring target 2 reaches the first light-receiving section 21A of the light-receiving section 20. The optical input waveform of the light-receiving section 20 has a pulse shape delayed by delay time DL with respect to the pulse shape illustrated in (A) of FIG. 8. The delay time DL corresponds to the time taken until the light emitted from the light-emitting section 10 is reflected by the distance-measuring target 2 and received by the light-receiving section 20. Therefore, by obtaining the delay time DL, it is possible to calculate the distance to the distance-measuring target 2.

In the calculation of the distance to the distance-measuring target 2 described above, there may be a deviation between the distance obtained in the calculation (measured distance) and the actual distance (actual distance). This deviation is due to, for example, circuitry delay or the like in the light-emitting section 10, the light-receiving section 20, and the processor 50.

FIG. 9 illustrates an example of the deviation between the actual distance and the distance measured by the distance-measuring device 1 in a case where the present technology is applied to the direct method. In FIG. 9, the horizontal axis represents an actual distance d1, and the vertical axis represents a measured distance d2 before calibration. In an ideal case where there is no deviation between the measured distance d2 and the actual distance d1, the relationship between the actual distance d1 and the measured distance d2 is represented by a straight line LN1 with a slope of “a1” (a1=1) and an intercept of “0”. In practice, however, the relationship between the actual distance dl and the measured distance d2 is often as indicated by a straight line LN2. This straight line LN2 has a slope of “a2” and an intercept of “b”. That is, the slope and the intercept of the straight line LN2 are different from the slope and the intercept of the straight line LN1.

In the present embodiment, the measured distance is calibrated as follows. The processor 50 calibrates the measured distance on the basis of the second pixel signal S2 outputted from the second light-receiving section 21B in response to other partial light (monitoring light L2) incident on the second light-receiving section 21B. Specifically, the processor 50 performs correction value table creation operation and normal operation (distance measuring). The correction value table creation operation is performed, for example, prior to the normal operation. The correction value table creation operation may be performed at any timing as long as the normal operation is not performed. In the correction value table creation operation, the processor 50 creates a correction value table on the basis of the second pixel signal S2. Specifically, while performing control to change emission timing of the monitoring light L2 to various timings, the processor 50 detects light-receiving timing at which the second light-receiving section 21B receives the monitoring light L2, and obtains the measured distance corresponding to each emission timing on the basis of the second pixel signal S2. On the other hand, the processor 50 multiplies an amount (time) of change in the emission timing, which is known for the processor 50, by the speed of light to obtain the actual distance. The processor 50 calculates a difference between the measured distance obtained on the basis of the second pixel signal S2 and the actual distance obtained from the amount (time) of change in the emission timing. The calculated difference value is a correction value corresponding to the measured distance obtained on the basis of the second pixel signal S2. The processor 50 creates the correction value table by obtaining the correction value for each emission timing. In the normal operation (distance measuring), on the basis of the first pixel signal S1, the processor 50 measures the time taken until the light emitted from the light-emitting section 10 is reflected by the distance-measuring target 2 to enter the light-receiving section 20, and calculates the distance to the distance-measuring target 2 from the obtained time. For each of the n×m pixels of the first light-receiving section 21A, the measurement of the time taken until the light emitted from the light-emitting section 10 is reflected by the distance-measuring target 2 to enter the light-receiving section 20, and the calculation of the measured distance to the distance-measuring target 2 based on the obtained time are performed. Further, the processor 50 refers to the correction value table created in advance on the basis of the second pixel signal S2 to obtain the correction value corresponding to the measured distance obtained from the first pixel signal S1, and calibrates the measured distance to the distance-measuring target 2 with the obtained correction value. The calibration of the distance to the distance-measuring target 2 is performed for each of the n×m pixels of the first light-receiving section 21A.

In the distance-measuring device 1 as described above, in the first cover part 30, partial light of the light emitted from the light-emitting section 10 is applied to the distance-measuring target 2, the reflected light L1R thereof entering the first light-receiving section 21A of the light-receiving section 20. Other partial light enters the second light-receiving section 21B of the light-receiving section 20 through the first cover part 30 and the second cover part 40. This makes it possible to provide the optical path of the monitoring light L2. It is possible to create the correction value table to be used for distance calibration from the second pixel signal S2 outputted by the second light-receiving section 21B receiving the monitoring light L2. Therefore, it is possible to correct the distance to the distance-measuring target 2 by referring to the correction value table, which increases accuracy of the distance to the distance-measuring target 2. That is, it is possible to calibrate the distance to the distance-measuring target 2 on the basis of the second pixel signal S2 outputted from the second light-receiving section 21B.

Further, in the distance-measuring device 1, the first cover part 30 having the first reflecting surface 31 is disposed on the light emission side of the light-emitting section 10, and the second cover part 40 having the second reflecting surface 41 is disposed on the light incidence side of the light-receiving section 20, which makes it possible to easily provide the optical path of the monitoring light L2. Furthermore, the first cover part 30 and the second cover part 40 are large enough for adjustment of the optical path of the monitoring light L2, which makes it possible to easily adjust the optical path of the monitoring light L2.

### [Effects]

In the present embodiment as described above, the first cover part having the first reflecting surface and the second cover part having the second reflecting surface are provided, which makes it possible to easily provide the optical path of the monitoring light for acquisition of the second pixel signal. Therefore, it is possible to easily calibrate the distance to the distance-measuring target on the basis of the second pixel signal.

### 2. MODIFICATION EXAMPLE 1

In the above embodiment, the second light-receiving section 21B has such a size as to be localized at a position corresponding to the vicinity of the middle of the first light-receiving section 21 in the Y-axis direction, but is not limited thereto. Alternatively, for example, the second light-receiving section 21B may extend elongated in one direction D (a direction parallel to the Y-axis direction). Further, the second reflecting surface 41 of the second cover part 40 may also extend in the one direction D to correspond to the second light-receiving section 21B extending in the one direction D.

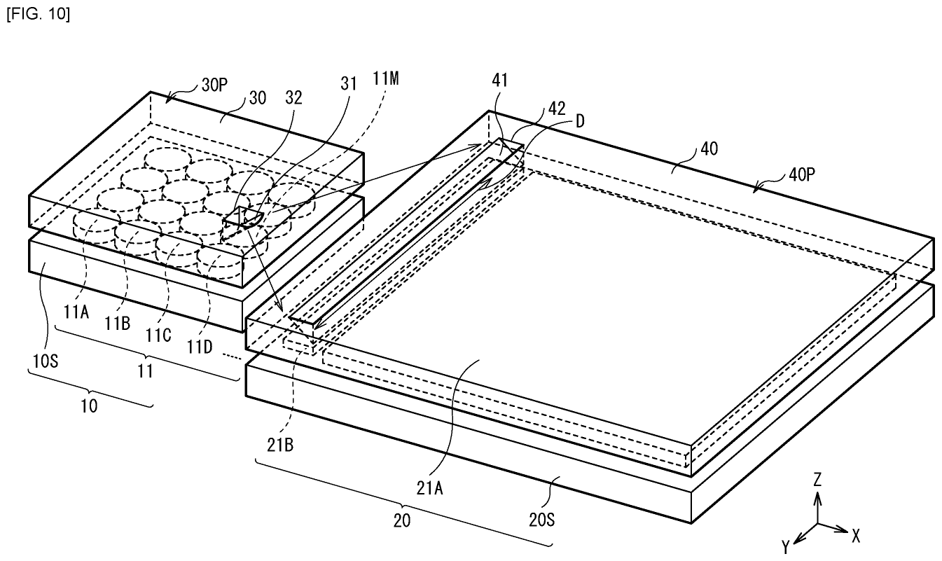

FIG. 10 illustrates an example configuration of a main part of a distance-measuring device 1A according to Modification Example 1. In this example, the second recess 42 of the second cover part 40 extends elongated in the one direction D, and the second reflecting surface 41 is provided so as to extend elongated in the one direction D. Further, the second light-receiving section 21B is provided so as to extend elongated in the one direction D. The one direction D in which the second reflecting surface 41 of the second cover part 40 and the second light-receiving section 21B extend is, for example, an extending direction (Y-axis direction) of one side of the first light-receiving section 21A on the light-emitting section 10 side.

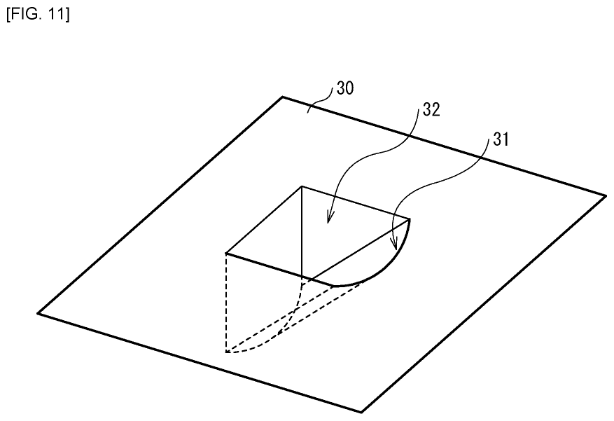

FIG. 11 illustrates, in enlarged view, an example configuration of the first recess 32 of the first cover part 30 of the distance-measuring device 1A. The first reflecting surface 31 of the first recess 32 provided in a portion of the first cover part 30 is provided obliquely with respect to the principal surface 30P of the first cover part 30, and further is a curved surface that is convex to the light-receiving section 20 side. As illustrated in FIG. 10, the first reflecting surface 31 that is a curved surface reflects the monitoring light L2 in the direction different from the direction of the distance-measuring target 2 so as to spread the monitoring light L2 in the same direction as the one direction D.

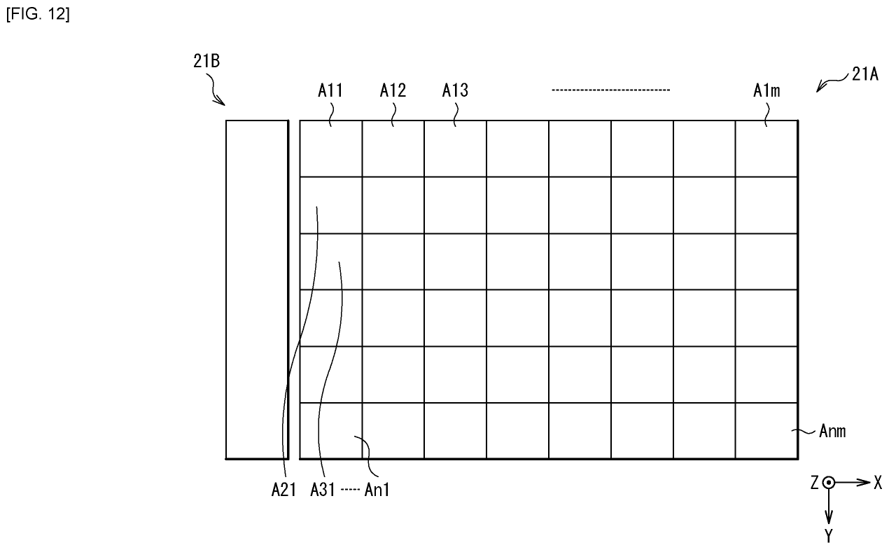

FIG. 12 illustrates an example configuration of the first light-receiving section 21A and the second light-receiving section 21B of the distance-measuring device 1A. In the present modification example, the second light-receiving section 21B is a single pixel having a shape extending elongated in the one direction D. The first light-receiving section 21A is similar to the first light-receiving section 21A illustrated in FIG. 4.

In the distance-measuring device 1A of the present modification example, the monitoring light L2 of the light emitted from the light-emitting section 10 is reflected by the first reflecting surface 31 of the first cover part 30 and guided in the direction of the second cover part 40 so as to be spread in the same direction as the one direction D. The monitoring light L2 spread in the same direction as the one direction D is reflected by the second reflecting surface 41 extending elongated in the one direction D and guided in the direction of the second light-receiving section 21B extending elongated in the one direction D to enter. Except for the above point, it is similar to the above embodiment.

In the distance-measuring device 1A of the present modification example, the monitoring light L2 is spread in the same direction as the one direction D, and is reflected by the second reflecting surface 41 to enter the second light-receiving section 21B extending elongated in the one direction D. This configuration therefore easily causes the monitoring light L2 to enter the second light-receiving section 21B. Thus, an allowable range of alignment in the one direction D between the first cover part 30 and the second cover part 40 is broadened. Further, the allowable range of alignment in the one direction D between the second cover part 40 and the light-receiving section 20 (second light-receiving section 21B) is broadened. This makes it possible to easily adjust the optical path of the monitoring light L2.

### 3. MODIFICATION EXAMPLE 2

In Modification Example 1 described above, the second light-receiving section 21B is configured to be a single pixel having a shape extending elongated in the one direction D, but is not limited thereto. Alternatively, for example, the second light-receiving section 21B may include a plurality of pixels arranged elongated in the one direction D.

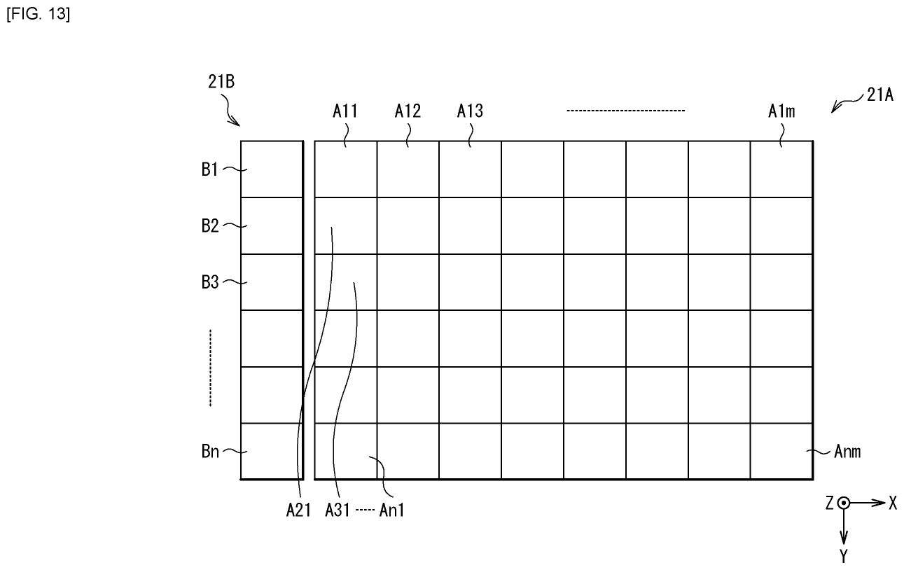

FIG. 13 illustrates an example configuration of the first light-receiving section 21A and the second light-receiving section 21B of a distance-measuring device 1B according to Modification Example 2. The second light-receiving section 21B includes a plurality of pixels (pixels B1, B2, . . . , Bn) arranged elongated in the one direction D. Although a plurality of pixels is arranged in one line in FIG. 13, there may be a plurality of lines. In the present modification example, each of the plurality of pixels (pixels B1, B2, . . . , Bn) may have the same structure as each of the n×m pixels (pixels A11 to Anm) of the first light-receiving section 21A. Except for the above point, it is similar to Modification Example 1 described above.

In the distance-measuring device 1B of the present modification example, the monitoring light L2 is spread in the same direction as the one direction D, and is reflected by the second reflecting surface 41 to enter the second light-receiving section 21B arranged elongated in the one direction D. This configuration therefore easily causes the monitoring light L2 to enter the second light-receiving section 21B. Thus, an allowable range of alignment in the one direction D between the first cover part 30 and the second cover part 40 is broadened. Further, the allowable range of alignment in the one direction D between the second cover part 40 and the light-receiving section 20 (second light-receiving section 21B) is broadened. This makes it possible to easily adjust the optical path of the monitoring light L2.

### 4. MODIFICATION EXAMPLE 3

In Modification Example 1 described above, the second recess 42 of the second cover part 40 extends elongated in the one direction D, and the second reflecting surface 41 extends elongated in the one direction D, but this example is non-limiting. Alternatively, for example, an end face of the second cover part 40 may be a second reflecting surface 44.

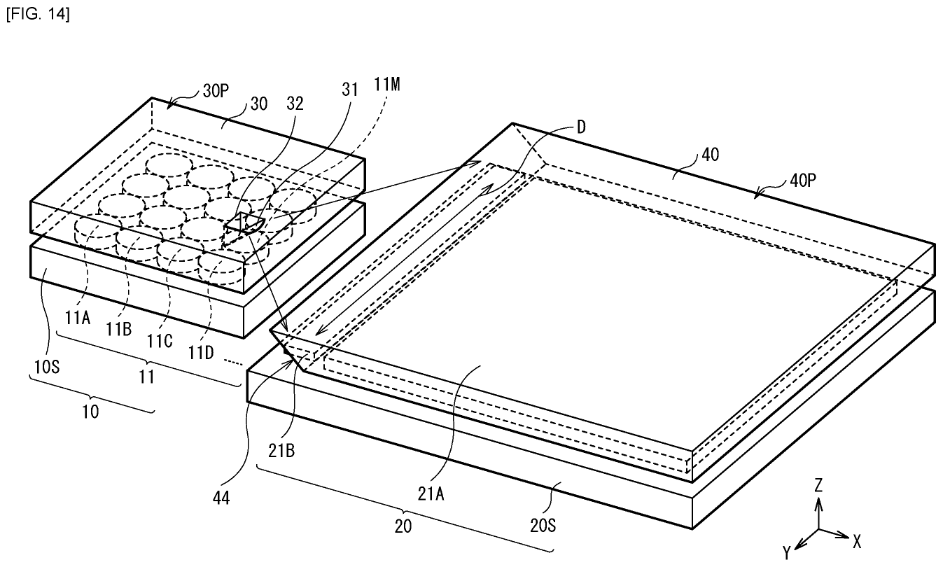

FIG. 14 illustrates an example configuration of a main part of a distance-measuring device 1C according to Modification Example 3. In this example, the end face of the second cover part 40 on the light-emitting section 10 side is an oblique surface having an angle of 45° with respect to the principal surface 40P of the second cover part 40, and the oblique surface is the second reflecting surface 44. The second reflecting surface 41 is provided so as to extend elongated in the one direction D. Further, the second light-receiving section 21B is provided so as to extend elongated in the one direction D. Except that the end face of the second cover part 40 described above is the oblique surface having an angle of 45° with respect to the principal surface 40P of the second cover part 40, it is similar to Modification Example 1 described above.

In the distance-measuring device 1C of the present modification example, a surface to be the second reflecting surface 44 is provided on the end face of the second cover part 40. Processing the end face of the second cover part 40 into the oblique surface having an angle of 45° with respect to the principal surface 40P of the second cover part 40 is easier than forming the second recess as in Modification Example 1.

Further, similarly, the first reflecting surface may be provided on an end face of the first cover part 30. That is, the end face of the first cover part 30 on the light-receiving section 20 side may be an oblique surface having an angle of 45° with respect to the principal surface 30P of the first cover part 30, and the oblique surface may be configured to be the first reflecting surface. In this case, of the light emitted from the light-emitting section 10, light that enters the end face of the first cover part 30 serves as the monitoring light L2.

### 5. MODIFICATION EXAMPLE 4

In Modification Example 3 described above, the second light-receiving section 21B extends elongated in the one direction D, but is not limited thereto. Alternatively, for example, the second light-receiving section 21B may not extend elongated in the one direction D, and may have such a size as to be localized at a position corresponding to the vicinity of the middle of the first light-receiving section 21 in the Y-axis direction.

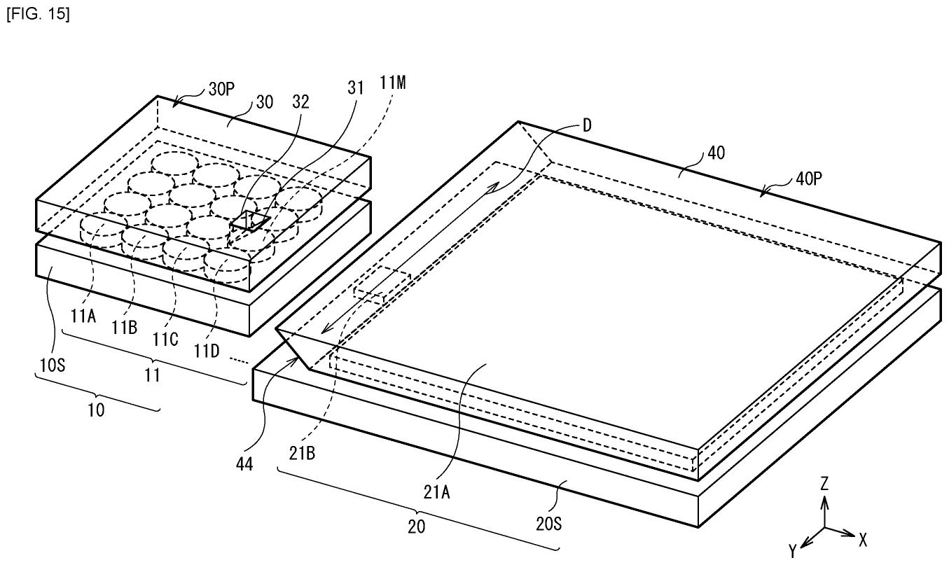

FIG. 15 illustrates an example configuration of a main part of a distance-measuring device 1D according to Modification Example 4. In this example, the end face of the second cover part 40 is the second reflecting surface 44 extending elongated in the one direction D, and the second reflecting surface 44 is provided so as to extend elongated in the one direction D. Further, the second light-receiving section 21B does not extend elongated in the one direction D, and is provided so as to be localized at a position corresponding to the vicinity of the middle of the first light-receiving section 21 in the Y-axis direction. The one direction D in which the second reflecting surface 44 extends is, for example, an extending direction (Y-axis direction) of one side of the first light-receiving section 21A on the light-emitting section 10 side.

In the distance-measuring device 1D of the present modification example, the monitoring light L2 of the light emitted from the light-emitting section 10 is reflected by the first reflecting surface 31 of the first cover part 30 to be guided in the direction of the second cover part 40. The monitoring light L2 is reflected by the second reflecting surface 44 and guided in the direction of the second light-receiving section 21B to enter. The first reflecting surface 31 may reflect the monitoring light L2 so as to spread it in the one direction D, or may reflect the monitoring light L2 so as not to spread it. In a case where the first reflecting surface 31 spreads the monitoring light L2 in the one direction D, only a portion of the monitoring light L2 spread in the one direction D enters the second light-receiving section 21B. In this case, even if the optical path of the monitoring light L2 is shifted in the one direction D, the light entering the second light-receiving section 21B hardly fluctuates. This broadens the allowable range of alignment in the one direction D between the second cover part 40 and the light-receiving section 20 (second light-receiving section 21B). This makes it possible to easily adjust the optical path of the monitoring light L2. In a case where the first reflecting surface 31 does not spread the monitoring light L2 in the one direction D, this configuration differs from the configuration illustrated in FIG. 2 in that the second reflecting surface 44 is provided on the end face of the second cover part 40 instead of in the second recess 42. It is advantageous in that the end face of the second cover part 40 is easier to process than the second recess 42.

### 6. MODIFICATION EXAMPLE 5

In the above embodiment, the first cover part 30 and the second cover part 40 are separate members, but this example is non-limiting. Alternatively, for example, the first cover part 30 and the second cover part 40 may be integrally configured.

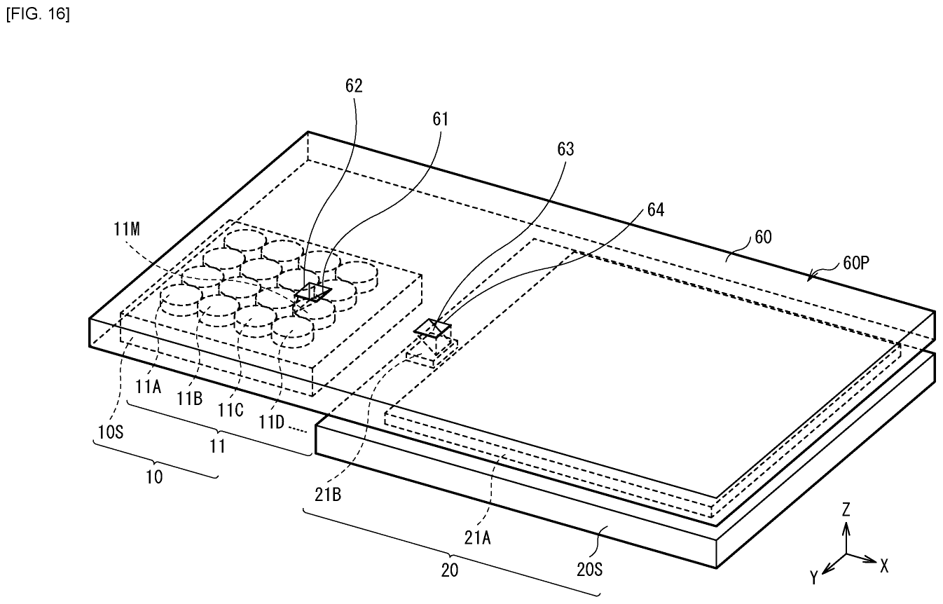

FIG. 16 illustrates an example configuration of a main part of a distance-measuring device 1E according to Modification Example 5. A common cover part 60 into which the first cover part 30 and the second cover part 40 have been integrated is provided on the light emission side of the light-emitting section 10 and the light incidence side of the light-receiving section 20. For example, the common cover part 60 is held by a holder or the like so as to be spaced apart from the light-emitting section 10 and the light-receiving section 20. The common cover part 60 includes a material that is transparent to the light emitted from the light-emitting section 10, and includes, for example, glass or plastic. The common cover part 60 has a plate-like shape as a whole. The common cover part 60 prevents dust or the like from adhering to the light-emitting section 10 and the light-receiving section 20, protecting the light-emitting section 10 and the light-receiving section 20 from the outside atmosphere.

In the present modification example, a first reflecting surface 61 is provided in a portion of the common cover part 60 on the light-emitting section 10 side. The first reflecting surface 61 is provided on an inner wall of a first recess 62 provided in a portion of the common cover part 60 on the light-emitting section 10 side. The first reflecting surface 61 is an oblique surface having an angle of 45° with respect to a principal surface 60P of the common cover part 60. Further, a second reflecting surface 63 is provided in a portion of the common cover part 60 on the light-receiving section 20 side. The second reflecting surface 63 is provided on an inner wall of a second recess 64 provided in a portion of the common cover part 60 on the light-receiving section 20 side. The second reflecting surface 63 is an oblique surface having an angle of 45° with respect to the principal surface 60P of the common cover part 60.

Like the light L1 illustrated in FIG. 1, partial light of the light emitted from the light-emitting section 10 is transmitted through the common cover part 60 to be guided in the direction of the distance-measuring target 2, and is reflected by the distance-measuring target 2 and transmitted again through the common cover part 60 to enter the first light-receiving section 21A. Further, like the light L2 illustrated in FIG. 1, other partial light of the light emitted from the light-emitting section 10 is reflected by the first reflecting surface 61 to be guided in a direction of the second reflecting surface 63 that is a direction different from the direction of the distance-measuring target 2, and is reflected by the second reflecting surface 63 to enter the second light-receiving section 21B. The relative position between the first reflecting surface 61 and the second reflecting surface 63 is determined such that other partial light of the light emitted from the light-emitting section 10 is able to take an optical path of being reflected by the first reflecting surface 61 to be guided in the direction of the second reflecting surface 63 and being reflected by the second reflecting surface 63 to enter the second light-receiving section 21B. Except for the above point, it is similar to the above embodiment.

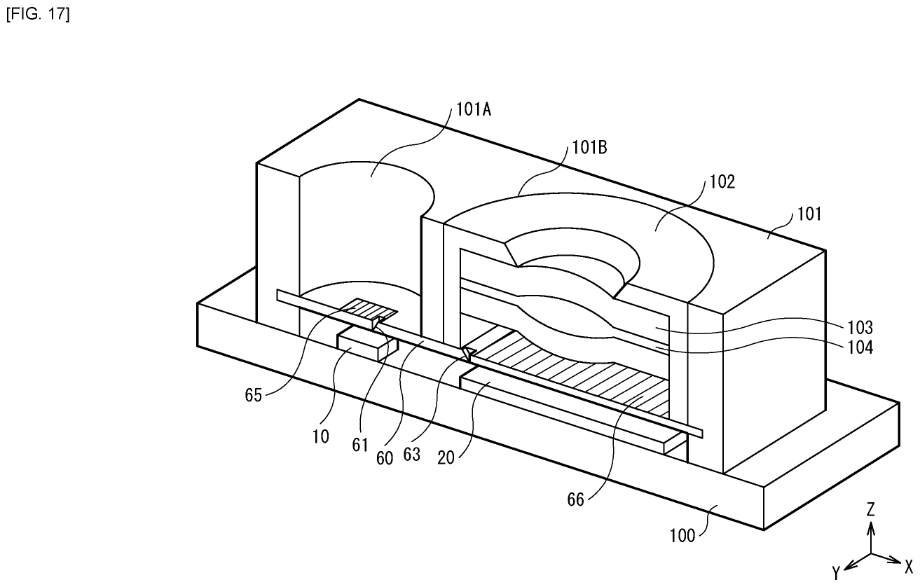

FIG. 17 illustrates an example configuration of the distance-measuring device 1E. The holder 101 is disposed on the substrate 100. The common cover part 60 is provided on the light emission side of the light-emitting section 10 and the light incidence side of the light-receiving section 20. The common cover part 60 is held by the holder 101. In the common cover part 60, a region overlapping the light-emitting section 10 is partly provided with the first reflecting surface 61, and a region overlapping the second light-receiving section 21B of the light-receiving section 20 is partly provided with the second reflecting surface 63. In a region of the common cover part 60 overlapping the light-emitting section 10, a light diffusing film 65 for diffusion of the light emitted from the light-emitting section 10 in the direction of the distance-measuring target 2 is formed. In a region of the common cover part 60 overlapping the light-receiving section 20, an infrared filter 66 for transmission of infrared light that is light from the light-emitting section 10 is provided.

In the distance-measuring device 1E of the present modification example, the common cover part 60 is provided, and the common cover part 60 has a configuration in which the first cover part and the second cover part are integrated. Therefore, the relative position between the first reflecting surface 61 and the second reflecting surface 63 is already determined. It is possible to provide the optical path of the monitoring light (light L2) only by disposing the one common cover part 60 on the light emission side of the light-emitting section 10 and the light incidence side of the light-receiving section 20. It is possible to perform alignment of the first reflecting surface 61 and the second reflecting surface 63 with respect to the light-emitting section 10 and the light-receiving section 20 only by adjusting alignment between the common cover part 60 and the light-receiving section 20 (second light-receiving section 21B), which makes it possible to easily adjust the optical path of the monitoring light L2.

### 7. MODIFICATION 6

In the above embodiment, a portion of the inner wall of the first recess 32 is made to function as the first reflecting surface 31, and a portion of the inner wall of the second recess 42 is made to function as the second reflecting surface 41, but this example is non-limiting. Alternatively, for example, a portion of the first cover part 30 may be provided with a first protrusion whose surface functions as a first reflecting surface, and a portion of the second cover part 40 may be provided with a second protrusion whose surface functions as a second reflecting surface.

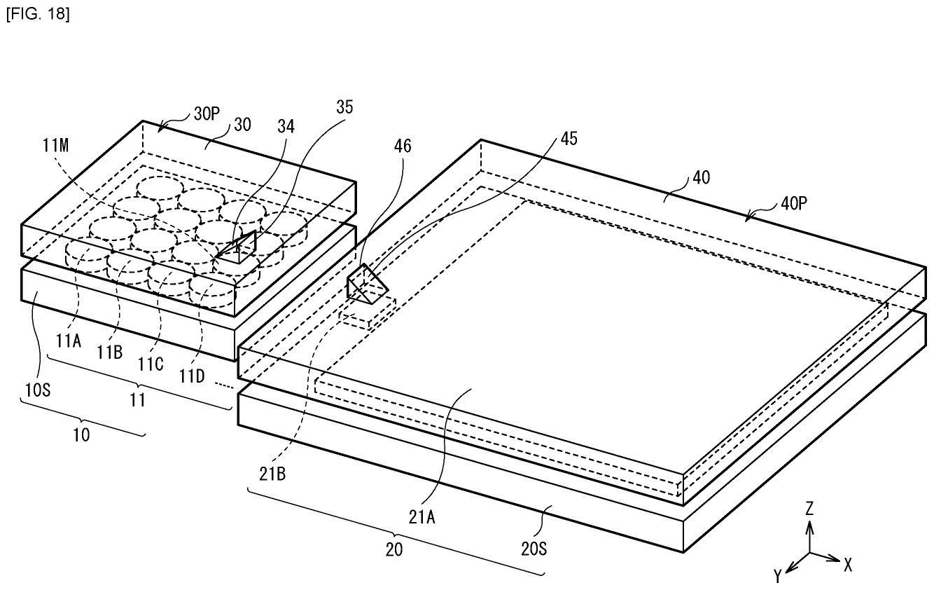

FIG. 18 illustrates an example configuration of a main part of a distance-measuring device 1F according to Modification Example 6. In this example, the first cover part 30 is partly provided with a first protrusion 35, and a portion of a surface of the first protrusion 35 is a first reflecting surface 34. Further, the second cover part 40 is partly provided with a second protrusion 46, and a portion of a surface of the second protrusion 46 is a second reflecting surface 45.

Like the light L1 illustrated in FIG. 1, partial light of the light emitted from the light-emitting section 10 is transmitted through the first cover part 30 to be guided in the direction of the distance-measuring target 2 and is reflected by the distance-measuring target 2 and transmitted through the second cover part 40 to enter the first light-receiving section 21A. Further, other partial light of the light emitted from the light-emitting section 10 is reflected by the first reflecting surface 34 provided on the surface of the first protrusion 35 to be guided in a direction of the second reflecting surface 45 that is a direction different from the direction of the distance-measuring target 2, and is reflected by the second reflecting surface 45 that is the surface of the second protrusion 46 to enter the second light-receiving section 21B.

In the distance-measuring device 1F of the present modification example, a protrusion having a reflecting surface is provided on each of the first cover part 30 and the second cover part 40. This may be preferably carried out in a case where it is easy to provide a protruding shape on the surface of the cover part, like plastic molding.

### 8. MODIFICATION EXAMPLE 7

In the above embodiment, the second light-receiving section 21B is located on the shortest line coupling a pixel included in the first light-receiving section 21A and the monitoring light-emitting body 11M, but is not limited thereto. Alternatively, for example, the second light-receiving section 21B may be provided at a position shifted from on the shortest line coupling the pixel included in the first light-receiving section 21A and the monitoring light-emitting body 11M.

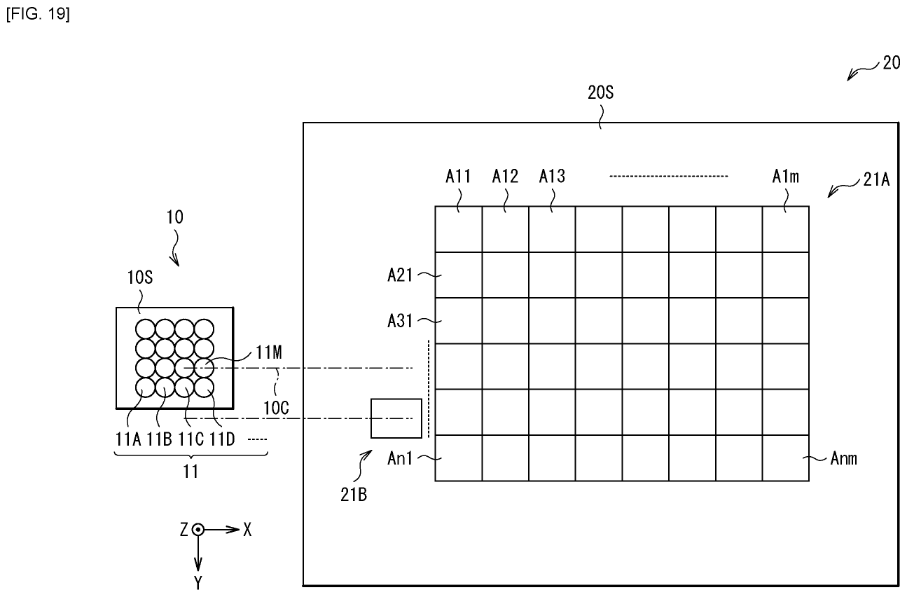

FIG. 19 illustrates an example configuration of the light-emitting section and the light-receiving section of a distance-measuring device 1G according to Modification Example 7. The second light-receiving section 21B is provided at a position shifted from on the shortest line coupling the pixel included in the first light-receiving section 21A and the monitoring light-emitting body 11M. The shortest line coupling the pixel included in the first light-receiving section 21A and the monitoring light-emitting body 11M is indicated by the dash-dot line 10C, and the second light-receiving section 21B is provided at a position shifted from on the dash-dot line 10C. In the present modification example, the first reflecting surface 31 is configured with its angle adjusted such that the first reflecting surface 31 reflects the monitoring light L2 in a direction of the second reflecting surface 41. Further, the second reflecting surface 41 is configured with its angle adjusted such that the second reflecting surface 41 reflects the light incident from the first reflecting surface 31 in the direction of the second light-receiving section 21B. Except for the above point, it is similar to the above embodiment.

The second light-receiving section 21B may not necessarily be located on the shortest line coupling the pixel included in the first light-receiving section 21A and the monitoring light-emitting body 11M.

### 9. MODIFICATION EXAMPLE 8

The above embodiment has described an example in which the measurement of the distance to the distance-measuring target 2 by the distance-measuring device 1 is performed by the direct method, but this example is non-limiting. Alternatively, for example, this distance may be measured by the indirect method. An example in which this distance is measured by the indirect method is described below.

FIG. 20 illustrates an example operation in a case of performing distance measuring by the indirect method by the distance-measuring device 1; (A) illustrates the optical output waveform (emitted pulse) of the light-emitting section 10, and (B) and (C) illustrate the optical input waveform (incident pulse) of the light-receiving section. In this example, the optical output waveform of the light-emitting section 10 ((A) of FIG. 20) is, for example, a pulse waveform with a duty ratio of 50%.

The optical input waveform of the light-receiving section 20 ((B) and (C) of FIG. 20) has a pulse shape delayed by predetermined time with respect to the pulse shape illustrated in (A) of FIG. 20. The delay time of the pulse corresponds to the time taken until the light (reflected light L1R) emitted from the light-emitting section 10 and reflected by the distance-measuring target 2 reaches the first light-receiving section 21A of the light-receiving section 20. Therefore, it is possible to calculate the distance to the distance-measuring target 2 on the basis of the delay time.

In the indirect method, a pixel of the first light-receiving section 21A accumulates signal charge Q1 in any period in a period T1 in which the light-emitting section 10 emits light, accumulates signal charge Q2 in any period in a period T2 in which the light-emitting section 10 does not emit light, and obtains a charge ratio between the signal charge Q1 and the signal charge Q2. In the examples of (B) and (C) of FIG. 20, the pixel of the first light-receiving section 21A accumulates the signal charge Q1 by detecting the incident pulse in a period TA of the period T1, and accumulates the signal charge Q2 by detecting the incident pulse in a period TB of the period T2. In the example of (B) of FIG. 20, the charge ratio of the signal charge Q1 to the signal charge Q2 is about 3:1, and in the example of (C) of FIG. 20, the charge ratio of the signal charge Q1 to the signal charge Q2 is about 1:1. Thus, the charge ratio of the signal charge Q1 to the signal charge Q2 varies depending on the delay time of the incident pulse. Therefore, by obtaining the charge-ratio, it is possible to obtain the delay time with high accuracy in units of, for example, picoseconds to nanoseconds. If the delay time is converted into the distance to the distance-measuring target 2, it is possible to obtain the distance to the distance-measuring target 2 with a resolution of 0.3 mm to 30 cm in a case where the delay time is measured on the order of picoseconds to nanoseconds, for example. It is to be noted that the period in which the signal charge Q1 is accumulated in the period T1 in which the light-emitting section 10 emits light and the period in which the signal charge Q2 is accumulated in the period T2 in which the light-emitting section 10 does not emit light may be changed as appropriate.

In the calculation of the distance to the distance-measuring target 2 described above, there may be a deviation between the distance obtained in the calculation (measured distance) and the actual distance (actual distance). This is due to, for example, circuit delay in the light-emitting section 10, the light-receiving section 20, and the processor 50, a circuit configuration of the light-receiving section 20, the shape of the emitted pulse, or the like.

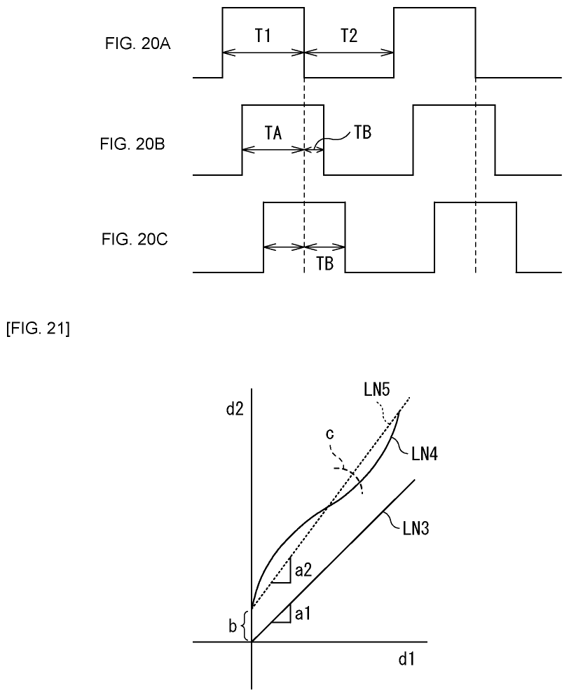

FIG. 21 illustrates an example of the deviation between the actual distance and the distance measured by the distance-measuring device 1 in a case where the present technology is applied to the indirect method. In an ideal case where there is no deviation between the measured distance and the actual distance, the relationship between the actual distance d1 and the measured distance d2 is represented by a straight line LN3 with a slope of “a1” (a1=1) and an intercept of “0”. In practice, however, the relationship between the actual distance d1 and the measured distance d2 is often as indicated by a curve LN4. This curve LN4 has a waviness component c. A straight line LN5 obtained by removing the waviness component c from this curve LN4 has a slope of “a2” and an intercept of “b”. That is, the slope and the intercept of the straight line LN5 are different from the slope and the intercept of the straight line LN3.

In the present embodiment, the measured distance is calibrated as follows. The processor 50 calibrates the measured distance on the basis of the second pixel signal S2 outputted from the second light-receiving section 21B pixel in response to other partial light (monitoring light L2) incident on the second light-receiving section 21B. Specifically, the processor 50 performs the correction value table creation operation and the normal operation (distance measuring) in a manner similar to that of the operation in the direct method described above. In the correction value table creation operation, the processor 50 creates the correction value table by detecting light-receiving timing at which the second light-receiving section 21B receives the monitoring light L2, while performing control to change emission timing of the monitoring light L2 to various timings. In the normal operation (distance measuring), the processor 50 calculates the distance to the distance-measuring target 2 on the basis of the first pixel signal S1, refers to the correction value table to obtain the correction value, and calibrates the measured distance to the distance-measuring target 2.

As described above, the present technology is also applicable to the indirect method. It is possible to more precisely measure the time taken until the light emitted from the light-emitting section 10 is reflected by the distance-measuring target 2 and received by the light-receiving section 20, and the distance to the distance-measuring target 2 converted from the time. Further, it is also possible to calibrate the distance to the distance-measuring target 2 obtained by the indirect method on the basis of the second pixel signal S2 outputted from the second light-receiving section 21B.

The above embodiment and Modification Examples 1 to 8 may be appropriately combined as necessary.

### 10. EXAMPLE OF APPLICATION TO MOBILE BODY

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

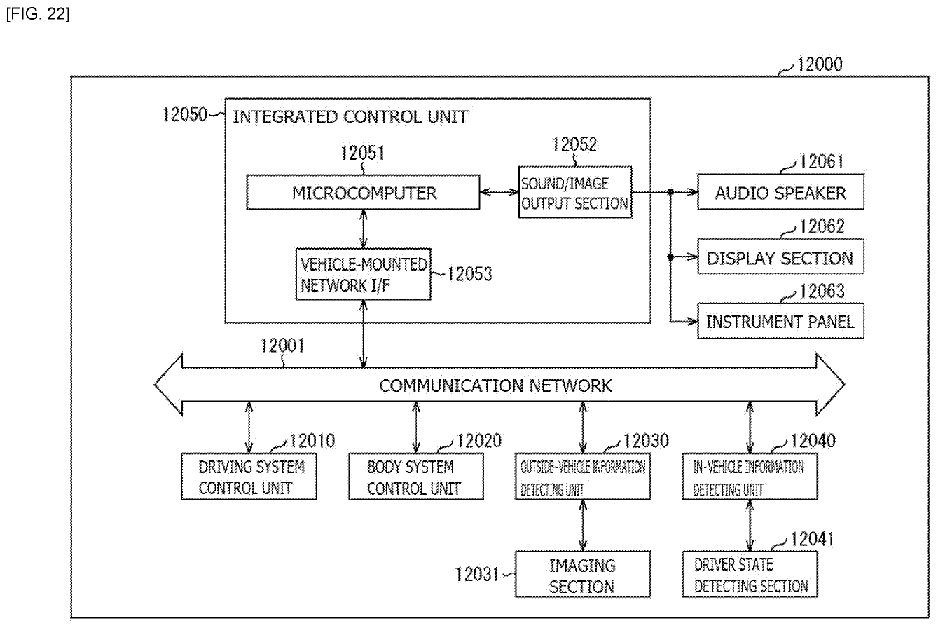

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

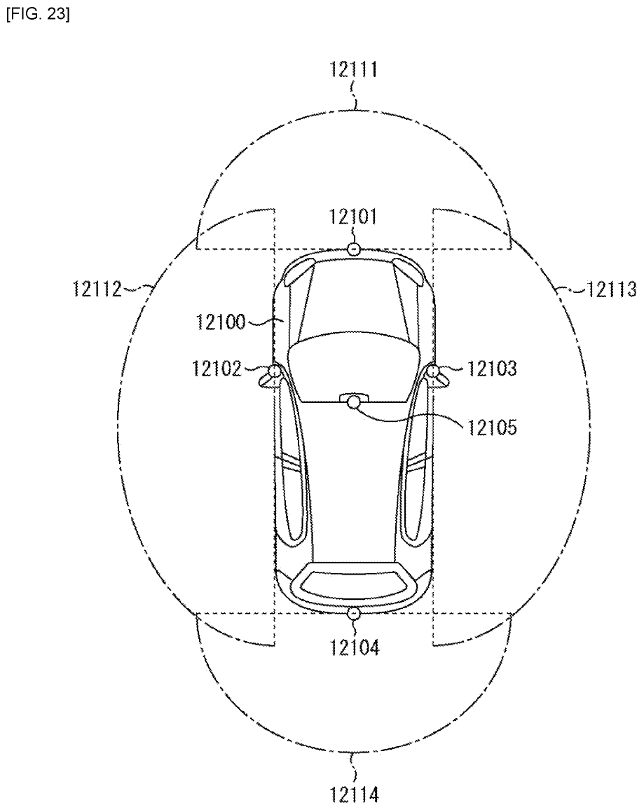

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the vehicle control system to which the technology according to the present disclosure may be applied. The technology according to the present disclosure may be applied to the imaging section 12031 among the above-described components. Specifically, the distance-measuring device 1 illustrated in FIG. 1 is applicable to the imaging section 12031. Applying the technology according to the present disclosure to the imaging section 12031 enables accurate measurement of a distance to, for example, a preceding vehicle, a subsequent vehicle, or another object.

Although the present technology has been described above with reference to some embodiments and modification examples, the present technology is not limited to these embodiments and the like, and may be modified in a variety of ways.

The above embodiment has described the distance-measuring device that measures the distance to the distance-measuring target, but this example is non-limiting. Alternatively, it may be a time measurement device that irradiates a target with light and measures time taken until the light returns.

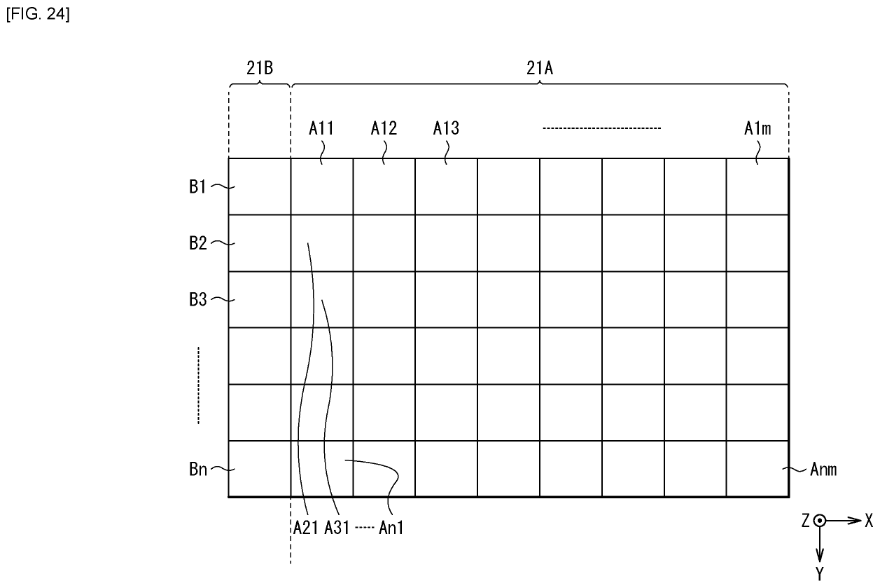

In the above embodiment and modification examples, as illustrated in FIG. 13 and the like, the first light-receiving section 21A and the second light-receiving section 21B are provided individually, but this example is non-limiting. Alternatively, for example, the first light-receiving section 21A and the second light-receiving section 21B may be integrally configured, like a distance-measuring device 1H illustrated in FIG. 24. Specifically, for example, one pixel array may be divided into two regions; one may be the first light-receiving section 21A, and the other may be the second light-receiving section 21B. In FIG. 24, each of the plurality of pixels (pixels B1, B2, . . . , Bn) of the second light-receiving section 21B may have the same structure as each of the n×m pixels (pixels A11 to Anm) of the first light-receiving section 21A.

It is to be noted that the effects described in this specification are merely illustrative and non-limiting, and other effects may be provided.

It is to be noted that the present technology may have the following configurations. According to the present technology having the following configurations, it is possible to more easily provide an optical path for calibration of a distance to a distance-measuring target.

(1)

An optical module including:

a light-emitting section configured to emit light;

a light-receiving section including a first light-receiving section and a second light-receiving section;

a first cover part provided on a light emission side of the light-emitting section, and configured to guide first light that is a portion of the light emitted from the light-emitting section in a direction of a target and guide second light that is another portion of the light emitted from the light-emitting section in a direction different from the direction of the target; and

a second cover part provided on a light incidence side of the light-receiving section, and configured to guide reflected light that is the first light reflected by the target in a direction of the first light-receiving section and guide the second light guided from the first cover part in a direction of the second light-receiving section.

(2)

The optical module according to (1), in which the first cover part has, in a portion of the first cover part, a first reflecting surface provided obliquely with respect to a principal surface of the first cover part and configured to reflect the second light in the direction different from the direction of the target.

(3)

The optical module according to (2), in which

the first cover part has a first recess provided in the portion of the first cover part, and

the first reflecting surface is an inner wall of the first recess.

(4)

The optical module according to (2), in which the first reflecting surface is an end face of the first cover part.

(5)

The optical module according to any one of (1) to (4), in which the second cover part has, in a portion of the second cover part, a second reflecting surface provided obliquely with respect to a principal surface of the second cover part and configured to reflect the second light in the direction of the second light-receiving section.

(6)

The optical module according to (5), in which

the second cover part has a second recess provided in the portion of the second cover part, and

the second reflecting surface is an inner wall of the second recess.

(7)

The optical module according to (5), in which the second reflecting surface is an end face of the second cover part.

(8)

The optical module according to any one of (1) to (7), in which

the second light-receiving section is provided to extend elongated in one direction,

the first cover part has, in a portion of the first cover part, a first reflecting surface provided obliquely with respect to a principal surface of the first cover part and configured to reflect the second light in the direction different from the direction of the target to spread the second light in a same direction as the one direction, and

the second cover part has, in a portion of the second cover part, a second reflecting surface provided obliquely with respect to a principal surface of the second cover part and configured to reflect the second light reflected by the first reflecting surface in the direction of the second light-receiving section.

(9)

The optical module according to (8), in which the second light-receiving section is a single pixel having a shape extending elongated in the one direction.

(10)

The optical module according to (8), in which the second light-receiving section includes a plurality of pixels arranged elongated in the one direction.

(11)

The optical module according to any one of (1) to (10), in which the first cover part and the second cover part are integrally configured.

(12)

The optical module according to any one of (1) to (11), in which the first light-receiving section and the second light-receiving section are integrally configured.

(13)

A distance-measuring device including:

a light-emitting section configured to emit light;

a light-receiving section including a first light-receiving section and a second light-receiving section;

a first cover part provided on a light emission side of the light-emitting section, and configured to guide first light that is a portion of the light emitted from the light-emitting section in a direction of a target and guide second light that is another portion of the light emitted from the light-emitting section in a direction different from the direction of the target;

a second cover part provided on a light incidence side of the light-receiving section, and configured to guide reflected light that is the first light reflected by the target in a direction of the first light-receiving section and guide the second light guided from the first cover part in a direction of the second light-receiving section; and

a processor configured to calculate a distance to the target on the basis of a first pixel signal outputted from the first light-receiving section in response to the reflected light incident on the first light-receiving section, and configured to calibrate the distance on the basis of a second pixel signal outputted from the second light-receiving section in response to the second light incident on the second light-receiving section.

(14)

The distance-measuring device according to (13), in which the processor is configured to calculate the distance by a direct method.

(15)

The distance-measuring device according to (13), in which the processor is configured to calculate the distance by an indirect method.

### REFERENCE SIGNS LIST

1 distance-measuring device
2 distance-measuring target
10 light-emitting section
10S light-emitting section substrate
11 light-emitting body
20 light-receiving section
20S light-receiving section substrate
21A first light-receiving section
21B second light-receiving section
30 first cover part
30P principal surface
31, 61 first reflecting surface
32, 62 first recess
33, 65 light diffusing film
40 second cover part
40P principal surface
41, 63 second reflecting surface
42, 64 second recess
43, 66 infrared filter
50 processor
60 common cover part
60P principal surface
S1 first pixel signal
S2 second pixel signal
100 substrate
101 holder
101A light-emitting section opening
101B light-receiving section opening
102 lens holder
103, 104 lens

This application claims the benefit of Japanese Priority Patent Application No. 2018-212133 filed with the Japan Patent Office on Nov. 12, 2018, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An optical module comprising:
a light-emitting section configured to emit light;
a light-receiving section including a first light-receiving section and a second light-receiving section;
a first cover part provided on a light emission side of the light-emitting section, and configured to guide first light that is a portion of the light emitted from the light-emitting section in a direction of a target and guide second light that is another portion of the light emitted from the light-emitting section in a direction different from the direction of the target; and
a second cover part provided on a light incidence side of the light-receiving section, and configured to guide reflected light that is the first light reflected by the target in a direction of the first light-receiving section and guide the second light guided from the first cover part in a direction of the second light-receiving section.

2. The optical module according to claim 1, wherein the first cover part has, in a portion of the first cover part, a first reflecting surface provided obliquely with respect to a principal surface of the first cover part and configured to reflect the second light in the direction different from the direction of the target.

3. The optical module according to claim 2, wherein
the first cover part has a first recess provided in the portion of the first cover part, and
the first reflecting surface is an inner wall of the first recess.

4. The optical module according to claim 2, wherein the first reflecting surface is an end face of the first cover part.

5. The optical module according to claim 1, wherein the second cover part has, in a portion of the second cover part, a second reflecting surface provided obliquely with respect to a principal surface of the second cover part and configured to reflect the second light in the direction of the second light-receiving section.

6. The optical module according to claim 5, wherein
the second cover part has a second recess provided in the portion of the second cover part, and
the second reflecting surface is an inner wall of the second recess.

7. The optical module according to claim 5, wherein the second reflecting surface is an end face of the second cover part.

8. The optical module according to claim 1, wherein
the second light-receiving section is provided to extend elongated in one direction,
the first cover part has, in a portion of the first cover part, a first reflecting surface provided obliquely with respect to a principal surface of the first cover part and configured to reflect the second light in the direction different from the direction of the target to spread the second light in a same direction as the one direction, and
the second cover part has, in a portion of the second cover part, a second reflecting surface provided obliquely with respect to a principal surface of the second cover part and configured to reflect the second light reflected by the first reflecting surface in the direction of the second light-receiving section.

9. The optical module according to claim 8, wherein the second light-receiving section is a single pixel having a shape extending elongated in the one direction.

10. The optical module according to claim 8, wherein the second light-receiving section includes a plurality of pixels arranged elongated in the one direction.

11. The optical module according to claim 1, wherein the first cover part and the second cover part are integrally configured.

12. The optical module according to claim 1, wherein the first light-receiving section and the second light-receiving section are integrally configured.

13. A distance-measuring device comprising:
a light-emitting section configured to emit light;
a light-receiving section including a first light-receiving section and a second light-receiving section;
a first cover part provided on a light emission side of the light-emitting section, and configured to guide first light that is a portion of the light emitted from the light-emitting section in a direction of a target and guide second light that is another portion of the light emitted from the light-emitting section in a direction different from the direction of the target;
a second cover part provided on a light incidence side of the light-receiving section, and configured to guide reflected light that is the first light reflected by the target in a direction of the first light-receiving section and guide the second light guided from the first cover part in a direction of the second light-receiving section; and
a processor configured to calculate a distance to the target on a basis of a first pixel signal outputted from the first light-receiving section in response to the reflected light incident on the first light-receiving section, and configured to calibrate the distance on a basis of a second pixel signal outputted from the second light-receiving section in response to the second light incident on the second light-receiving section.

14. The distance-measuring device according to claim 13, wherein the processor is configured to calculate the distance by a direct method.

15. The distance-measuring device according to claim 13, wherein the processor is configured to calculate the distance by an indirect method.
